(19) United States
(12) Patent Application Publication
(10) Pub. No.: US 2025/0101862 A1
(43) Pub. Date: Mar. 27, 2025

(54) AUTOMATICALLY LOCATING AND TRACKING A TRANSIENT OBJECT IN A HYDROCARBON WELL CONDUIT

(71) Applicant: Halliburton Energy Services, Inc., Houston, TX (US)

(72) Inventors: Oluwatosin Ogundare, The Woodlands, TX (US); Krishna Babu Yerubandi, Houston, TX (US); Arideep Bhowmick, Kolkata (IN); Antonio Acquaah, Houston, TX (US); Chalice Young, Houston, TX (US); Philippe Quero, Houston, TX (US); Stephen Newman, Banchory (GB); Graham Jack, Newburgh (GB); David Bennett, Houston, TX (US)

(21) Appl. No.: 18/476,149

(22) Filed: Sep. 27, 2023

(51) Int. Cl. E21B 47/095; G06F 30/27

(52) U.S. Cl. CPC E21B 47/095; G06F 30/27; E21B 2200/20

(57) ABSTRACT

A machine learning-based system for automatically locating and tracking a transient object in a conduit of interest associated with a hydrocarbon well operation. The system may train a machine learning model using pressure data received from a conduit monitoring system that operates by introducing a pressure wave into the fluid within a conduit and using a sensor to measure the magnitude of pressure waves reflected by a transient object in the conduit. The pressure data can be filtered to remove noise and focus on a frequency range of interest prior to being used to generate a training dataset for training the machine learning model. The machine learning model may be trained to generate a predictive model that can predict the location and movement of a transient object in a conduit of interest based on new pressure measurements associated with the conduit of interest.

### TECHNICAL FIELD

The present disclosure relates generally to hydrocarbon well operations, and more particularly although not necessarily exclusively, to the automated location and tracking of transient objects in hydrocarbon well conduits.

### BACKGROUND

Transient objects may occasionally be present in a conduit of a hydrocarbon well operation. Such a conduit may be, for example, a wellbore, a flowline, or a pipeline. A transient object may be an undesirable blockage comprised of some material that travels through the conduit. Alternatively, a transient object may be a plug that is used to separate fluids during a cementing operation of a hydrocarbon well operation, or a top plug that indicates the end of a cementing operation. A transient object may also be what is commonly referred to in the industry as a pig that is intentionally introduced into a conduit of a hydrocarbon well operation for purposes of inspection or cleaning. A blockage, a plug, a pig, or another transient object may substantially or completely block the flow of fluid through a conduit in which the transient object is present. For example, during a pigging operation, the conduit into which the pig has been introduced remains effectively blocked as the pig makes its way from an introduction point to a removal point. Whether a transient object is an unintentional blockage or a deliberately introduced object, it is beneficial to a hydrocarbon well operator to be able to locate and track the movement of the transient object in real time. In the case of a blockage, for example, knowledge of the location and movement (e.g., speed of travel) of the blockage may be useful for purposes of remediation. In the case of a pigging operation, for example, knowledge of the location and movement of the pig may be used to determine when the pig should arrive at its extraction point or to determine if the pig has become stuck.

### BRIEF DESCRIPTION OF THE DRAWINGS

FIG. 1 is a schematic diagram of system for locating and tracking a transient object in a wellbore of a hydrocarbon well operation according to one example of the present disclosure.

FIG. 2 depicts a computing environment including a computing system configured to execute a machine learning model for locating and tracking a transient object in a hydrocarbon well conduit according to one example of the present disclosure.

FIG. 3 is a block diagram of a computing system for locating and tracking a transient object in a hydrocarbon well conduit according to one example of the present disclosure.

FIG. 4 is a graphical representation of overlaid pressure data for a time period of interest received by a transient object locating and tracking system from multiple test operations performed by a conduit monitoring system according to one example of the present disclosure.

FIG. 5 is a graphical representation of a predicted location of a transient object in a conduit of interest as predicted by a transient object locating and tracking system based on the pressure data associated with each test operation indicated in FIG. 4 according to one example of the present disclosure.

FIG. 6 illustrates various information that may be presented in a notification generated by a transient object locating and tracking system relative to a transient object in a conduit of interest according to one example of the present disclosure.

FIG. 7 is a flowchart of a method of training a machine learning model to locate and track a transient object in a hydrocarbon well conduit of interest according to one example of the present disclosure.

### DETAILED DESCRIPTION

Certain aspects and examples described herein relate to a system for locating and tracking a transient object in a hydrocarbon well operation conduit (also referred to herein as “conduit”) by training a machine learning model and applying the trained machine learning model to pressure measurements obtained from a conduit monitoring system for a conduit of interest. Conduit monitoring system examples may be configured to record pressure within a conduit and can be installed to, for example and without limitation, hydrocarbon well operation conduits in the form of wellbore casings, flowlines, and pipelines. Conduit monitoring system examples may use a combination of sensors and data acquisition devices to generate data indicative of pressure conditions inside a conduit. The pressure data may serve as training data and can be provided to a computing device, such as a computing device of a system for locating and tracking transient objects (i.e., a transient object locating and tracking system), for training a machine learning model to generate a predictive model. The predictive model can subsequently be applied to pressure measurements for a conduit of interest to predict the location and movement of a transient object in the conduit of interest.

A conduit monitoring system used to provide data to a system, such as a transient object locating and tracking system, operates by introducing a pressure wave into the fluid flowing in the conduit, and using one or more sensors to measure the magnitude of pressure wave reflections caused by transient object anomalies such as pigs or blockages in the conduit. Pressure data generated by the sensor(s) can be recorded, stored or otherwise collected, and can be provided to a transient object locating and tracking system for purposes of training a machine learning model, or for predictive purposes when the pressure data is associated with a conduit of interest.

Pressure data collected by a conduit monitoring system can be used to train a machine learning model. For example, pressure data collected by a conduit monitoring system can be automatically transmitted to a computing device for use in training a machine learning model. The computing device may be part of a transient object locating and tracking system. The computing device may access pressure data in a conduit pressure dataset produced by the conduit monitoring system to generate a training dataset and to train a machine learning model using the training dataset to produce a trained (predictive) model. The trained model may subsequently be applied to new pressure data associated with a conduit of interest to predict the location and movement of a transient object in the conduit of interest.

The machine learning model is preferably also trained on at least one key attribute, which may be a plurality of key attributes. For example, the machine learning model can be trained to recognize the point in the collected pressure data at which introduction of a pressure wave into a monitored conduit begins (e.g., at valve opening). This typically results in the largest point of created acoustic energy in the conduit during a test. Similarly, the machine learning model can be trained to recognize the point in the collected pressure data at which the mechanism used to introduce the pressure pulse into the monitored conduit is turned off (e.g., at valve closing), or the point at which the pressure in the conduit begins to recover after introduction of the pressure wave. The slope of the pressure data or the slope of the first derivative of the pressure data at one or more given points during a test may also be analyzed in this regard. For purposes of generating a first (and perhaps second) derivative of the pressure and training the machine learning model to recognize such key attributes, the pressure data may be transformed by a technique such as fast Fourier transformation (FFT).

The machine learning model can further be trained on other key attributes associated with the conduit being monitored, such as for example, the length of the conduit. Training the machine learning model using the length of the conduit as a key attribute, for example, can further allow for training of the machine learning model on pressure data collected only during a time period of interest, while pressure data collected prior to or after the time period of interest can be excluded. This can further help the machine learning model to understand what the pressure data of interest looks like and to align the pressure data with the goal of minimizing standard deviation or minimized mean average between transient object location calculations.

It is possible for different examples of the machine learning model to be trained using supervised, semi-supervised, or unsupervised machine learning methods. In at least one example, the trained (predictive) model may be, for example, a classification model. In another example, the predictive model may instead be a regression model. Artificial neural networks and deep learning may also be employed to generate a predictive model.

An example of a transient object locating and tracking system can report the location and movement (e.g., direction, speed) of a transient object in a conduit, such as to personnel responsible for operating or maintaining the affected conduit of the hydrocarbon well operation, or a pig placed into the conduit. Another example of a transient object locating and tracking system can, in response to determining the location of a transient object, determine, initiate or control a remediation operation, or anticipate or schedule removal of a pig, such as at a pig receiving station. Using a transient object locating and tracking system to apply a properly trained machine learning model to sensor data obtained from a conduit monitoring system as described herein, can result in accurate location and tracking of a transient object in a conduit.

In addition to using transient object locating and tracking system examples to locate and track a transient object in a given conduit, a transient object locating and tracking system can use sensor data from a conduit monitoring system in various other ways. For example, a transient object locating and tracking system can use sensor data collected from an existing hydrocarbon well flowline, pipeline, or wellbore, in a predictive modeling application relative to future hydrocarbon well operations, such as but not limited to wellbore, flowline, or pipeline design, maintenance scheduling, etc.

Illustrative examples follow, and are given to introduce the reader to the general subject matter discussed herein rather than to limit the scope of the disclosed concepts. The following sections describe various additional features and examples with reference to the drawings in which like numerals indicate like elements, and directional descriptions are used to describe the illustrative aspects, but, like the illustrative aspects, should not be used to limit the present disclosure.

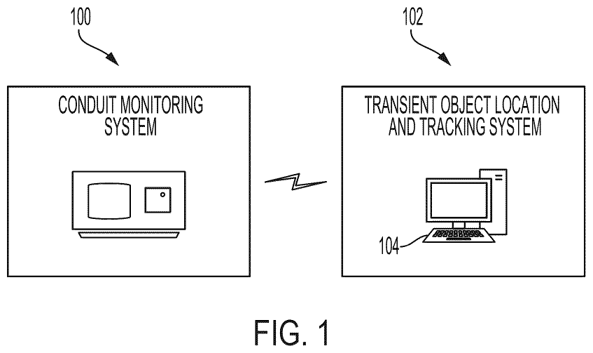

A conduit monitoring system 100 for monitoring and reporting the conditions within a conduit of interest is depicted in FIG. 1, along with a transient object locating and tracking system 102 that is communicatively coupled to the conduit monitoring system 100. The conduit monitoring system 100 operates by introducing a pressure wave into the fluid within a conduit, and as the pressure wave propagates therein, uses one or more sensors to measure the magnitude of reflected pressure waves caused by depositions or leaks in the conduit.

The conduit monitoring system 100 records, stores or otherwise collects pressure data generated by the sensor(s) in response to the receipt of pressure wave reflections traveling in the conduit. The pressure data collected by the conduit monitoring system 100 can be transmitted by the conduit monitoring system 100 to a computing device for analysis or for use in training a machine learning model. As indicated, the computing device 104 is part of the transient object locating and tracking system 102 in this example. The pressure data may be transmitted to the computing device 104 of the transient object locating and tracking system 102 as determined by the conduit monitoring system 100, at the request of the computing device 104 of the transient object locating and tracking system 102, or otherwise. The computing device 104 of the transient object locating and tracking system 102 can reside locally to the components of the conduit monitoring system 100 and may be communicatively coupled thereto via a local interface. Alternatively, the computing device 104 and the transient object locating and tracking system 102 can reside remotely from the components of the conduit monitoring system 100, and the computing device 104 may receive pressure data from the conduit monitoring system 100 over a network, such as but not limited to the Internet. Communications between the conduit monitoring system 100 and the transient object locating and tracking system 102 may be wired or wireless communications. Wireless communications between the conduit monitoring system 100 and the computing device 104 of the transient object locating and tracking system 102 are indicated in FIG. 1 for purposes of illustration.

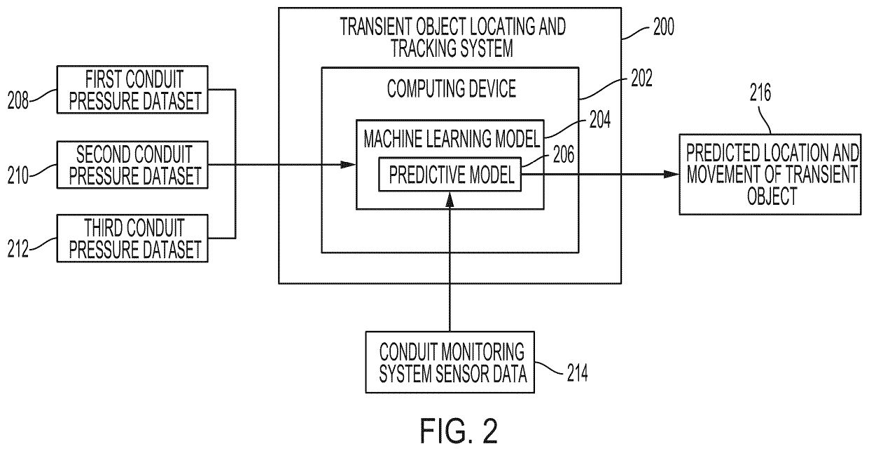

FIG. 2 depicts one example of a computing environment including a transient object locating and tracking system 200 having a computing device 202 configured to train a machine learning model 204 and to execute a trained (predictive) model 206 to locate and track a transient object in a hydrocarbon well conduit. In other examples, a computing device used to train a machine learning model may be separate from the transient object locating and tracking system 200. The machine learning model may be trained using pressure data samples in one or more of a first conduit pressure dataset 208, a second conduit pressure dataset 210, and a third conduit pressure dataset 212, as is described in more detail below. In some examples, it is possible to train the machine learning model 204 using only one or the other of the first conduit pressure dataset 208 and the second conduit pressure dataset 210, or the first conduit pressure dataset 208 and the third conduit pressure dataset 212. The first conduit pressure dataset 208, second conduit pressure dataset 210, and third conduit pressure dataset 212 may be stored in a memory (e.g., on a local drive) of the computing device 202, or on a network drive, a cloud storage system, or any other applicable storage medium.

The computing device 202 of the transient object locating and tracking system 200 can utilize existing pressure data for training the machine learning model 204, particularly pressure data obtained through past operation of a conduit monitoring system, such as but not limited to the conduit monitoring system 100 shown in FIG. 1, and correspondingly described above. In an example, the first conduit pressure dataset 208 may be pressure data recorded or otherwise obtained by a sensor of a conduit monitoring system when monitoring an ideal hydrocarbon well conduit-meaning that the conduit contains no transient objects or other anomalies such as depositions or leaks. In an example, the second conduit pressure dataset 210 may be pressure data recorded or otherwise obtained by a conduit monitoring system when monitoring a hydrocarbon well conduit in which is present a transient object comprising a blockage caused by some type of material (e.g., a hydrate). In an example, the third conduit pressure dataset 212 may be pressure data recorded or otherwise obtained by a conduit monitoring system when monitoring a hydrocarbon well conduit in which is present a transient object comprising a pig.

In an example, the machine learning model can be trained using only a portion of the available pressure data of the first conduit pressure dataset 208, the second conduit pressure dataset 210, or the third conduit pressure dataset 212, while another portion or the pressure data of the first conduit pressure dataset 208, the second conduit pressure dataset 210, or the third conduit pressure dataset 212, can be withheld for subsequent use in validating the predictive model. That is, once the predictive model 206 is generated through training of the machine learning model 204, the predictive model 206 may be validated against the portion of the first conduit pressure dataset 208, the second conduit pressure dataset 210, or the third conduit pressure dataset 212, held in reserve. It is also possible to validate the predictive model 206 against results generated relative to the same pressure data by a physics-based model that is known to be accurate.

The machine learning model 204 may be trained, according to an example, using a supervised learning method. In a supervised learning method example, the pressure data samples contained in the first conduit pressure dataset 208, the second conduit pressure dataset 210, and the third conduit pressure dataset 212 is labeled. As such, the machine learning model 204 knows during the training process that the pressure data of the first conduit pressure dataset 208 is representative of pressure measurements made by a conduit monitoring system relative to an ideal hydrocarbon well conduit. Likewise, the machine learning model 204 knows during the training process that the pressure data of the second conduit pressure dataset 210 is representative of pressure signals measurements made by a conduit monitoring system relative to a hydrocarbon well conduit that contains a blockage other than a pig, and that the pressure data of the third conduit pressure dataset 212 is representative of pressure signals measurements made by a conduit monitoring system relative to a hydrocarbon well conduit that contains a pig. It is also possible to train the machine learning model 204 using a single conduit pressure dataset comprising appropriately labeled pressure data that is representative of the pressure within each of an ideal conduit, a conduit containing a blockage other than a pig, and a conduit containing a pig.

In an example, a supervised learning method may be a supervised classification learning method executed by a classification algorithm such that the predictive model 206 is a classification model. Various types of classification algorithms may be utilized for this purpose, such as without limitation, logistic regression and random forest classification algorithms. Other appropriate classification algorithms known to those of skill in the art may also be used. The output of the predictive model 206 in such an example may be a prediction (predictive output) 216 of the location and movement (if any) of a transient object in a conduit of interest based on new pressure (sensor) data 214 from an associated conduit monitoring system to which the predictive model 206 is subsequently applied.

The machine learning model 204 may also be trained, according to an example, using a semi-supervised learning method. In a semi-supervised learning method example, only some of the pressure data contained in the first conduit pressure dataset 208, the second conduit pressure dataset 210, and the third conduit pressure dataset 212 is labeled, and the machine learning model 204 can be trained only on the partially labeled pressure data in the second conduit pressure dataset 210 or the third conduit pressure dataset 212, or on the partially labeled pressure data in both the first conduit pressure dataset 208 in combination with the second conduit pressure dataset 210 or the third conduit pressure dataset 212. As such, the machine learning model 204 is unaware whether some of the training data on which it is trained comprises pressure data that is representative of an ideal conduit or a conduit having a deposition or a leak. To overcome this issue, learning that occurs during training of the machine learning model 204 on pressure data that is labeled can be used to predict a label for the unlabeled pressure data. The pressure data with predicted labels can then be used to retrain the machine learning model 204 or to train a new machine learning model. The predictive model 206 resulting from training the machine learning model 204 using a semi-supervised learning method, may again be a classification model.

The machine learning model 204 may also be trained, according to an example, using an unsupervised learning method. In an unsupervised learning method example, the machine learning model 204 may be trained using pressure data from a conduit monitoring system that is known to be associated with an ideal conduit to produce a predictive model 206 that is reflective of normal conduit conditions. Once the normal predictive model 206 has been generated, a predictive algorithm thereof can identify and track a transient object in a conduit of interest from anomalies in new pressure (sensor) data 214 to which the predictive model 206 is subsequently applied, on the basis of an amount of deviation from the normal model. The predictive algorithm may employ, without limitation, clustering, anomaly detection, or other techniques to this end.

According to some examples, a supervised or unsupervised artificial neural network (ANN) can also be trained and utilized to locate and track the movement of a transient object. A deep learning network can also be trained and employed. Ensembling techniques, such as, for example, bootstrapping or aggregation, may also be utilized regardless of the modeling method used. Ensembling techniques may also be used to reduce model variance. Feature engineering techniques may also be employed during training of the machine learning model, such as for purposes of extracting features (e.g., key attributes) from the raw training data and using the features to improve the machine learning model training process. Likewise, feature selection techniques can be used to remove features from the raw training data that are not necessary to training of the machine learning model.

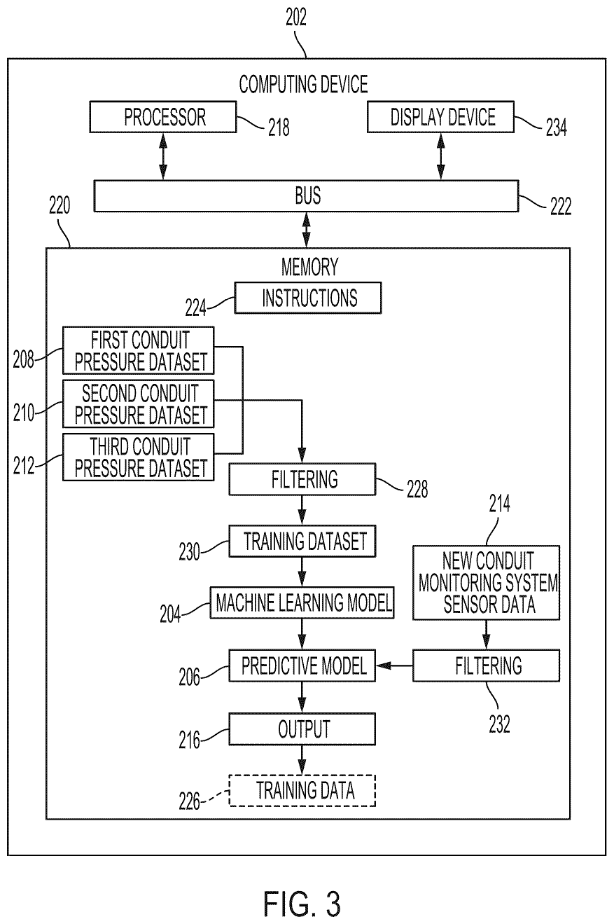

FIG. 3 is a block diagram of one example of the computing device 202 of the transient object locating and tracking system 200, which may be used to train the machine learning model 204. The computing device 202 can also be used to execute the predictive model 206 to locate and track a transient object in a hydrocarbon well conduit. While FIG. 3 depicts the computing device 202 as including certain components, other examples may involve more, fewer, or different components than are shown in FIG. 3. In an example, the computing device 202 may be implemented as the transient object locating and tracking system 200, as described above with respect to FIG. 2.

As shown, the computing device 202 includes a processor 218 communicatively coupled to a memory 220 by a bus 222. The processor 218 can include one processor or multiple processors. Non-limiting examples of the processor 218 include a Field-Programmable Gate Array (FPGA), an application specific integrated circuit (ASIC), a microprocessor, or any combination of these. Instructions 224 may be stored in the memory 220. The instructions are executable by the processor for causing the processor to perform various operations. In some examples, the instructions 224 can include processor specific instructions generated by a compiler or an interpreter from code written in any suitable computer-programming language, such as C, C++, C#, or Java.

The memory 220 can include one memory device or multiple memory devices. The memory 220 can be non-volatile and may include any type of memory device that retains stored information when powered off. Non-limiting examples of the memory 220 include electrically erasable and programmable read-only memory (EEPROM), flash memory, or any other type of non-volatile memory. At least some of the memory device includes a non-transitory computer-readable medium from which the processor 218 can read instructions 224. A non-transitory computer-readable medium can include electronic, optical, magnetic, or other storage devices capable of providing the processor 218 with the instructions 224 or other program code. Non-limiting examples of a non-transitory computer-readable medium include magnetic disk(s), memory chip(s), ROM, random-access memory (RAM), an ASIC, a configured processor, optical storage, or any other medium from which a computer processor can read the instructions 224.

The computing device 202 may include the machine learning model 204, which can be trained using pressure data samples in the first conduit pressure dataset 208, the second conduit pressure dataset 210, or the third conduit pressure dataset 212. The machine learning model 204 may be trained using the pressure data samples in the first conduit pressure dataset 208, the second conduit pressure dataset 210, or the third conduit pressure dataset 212 by the computing device 202 to generate the predictive model 206. The computing device 202 can execute the predictive model 206 on new pressure data 214 received from or produced by a conduit monitoring system to generate the predictive output 216 relative to the location and movement of a transient object in a conduit of interest associated with the pressure data to which the predictive model 206 was applied. When the machine learning model 204 is trained using a semi-supervised learning method, the output 216 of the predictive model 206 may include predicted labels for unlabeled data in the first conduit pressure dataset 208, the second conduit pressure dataset 210, or the third conduit pressure dataset 212, which can function as additional training data 226 that can be used to further train the machine learning model 204 or to train a new machine learning model.

The output 216 can provide useful information to a user of the transient object locating and tracking system 200. For example, the output may generate a notification that at least a identifies a location of the transient object in the conduit of interest, and can also include movement information (e.g., speed, direction) associated with the transient object. The output may predict a length of time required for the transient object to reach a particular location in the conduit of interest, such as when a pig will reach a preexisting removal point. The (predictive) output 216, including a notification generated as part of the output, may be textual and/or graphical in nature. In an example, the output 216, in the form of a generated notification or otherwise, may be presented on a display 234 that communicates with the processor 218 via the bus 222.

Pressure data received by a transient object locating and tracking system will commonly be affected by noise, such as pump noise or other extraneous noise, and may occur across a wide frequency range. Consequently, examples of the computing device 202 of the transient object locating and tracking system 200 can include filtering functionality. For example, as indicated in FIG. 3, the computing device 202 may execute a first filtering operation 228 that can be applied to pressure data samples in the first conduit pressure dataset 208, the second conduit pressure dataset 210, or the third conduit pressure dataset 212 to generate a training dataset 230 containing filtered pressure data samples. The first filtering operation 228 can also be applied to a single conduit pressure dataset comprising the combined pressure data samples of the first conduit pressure dataset 208, the second conduit pressure dataset 210, and the third conduit pressure dataset 212 to generate a training dataset 230 containing filtered pressure data samples. The training dataset 230 of filtered pressure data samples can thereafter be used to train the machine learning model 204. The computing device 202 may also execute a second filtering operation 232 that can be applied to new conduit monitoring system pressure data associated with a conduit of interest prior to application of the predictive model 206 thereto.

In an example, the first filtering operation 228 can be utilized to remove noise from the collected pressure data samples prior to using the pressure data samples to generate the training dataset 230 for training the machine learning model 204. The first filtering operation 228 may also focus the training dataset 230 on a frequency range likely to be of interest to the transient object locating and tracking system 200. In an example, the second filtering operation 232 can be applied for similar purposes to new pressure data associated with a conduit of interest to which the predictive model 206 is applied. Either or both of the first filtering operation 228 and the second filtering operation 232 may be a two-step process. For example, a low-pass filter such as, without limitation, a Butterworth filter, may be initially applied to collected pressure data samples to remove or attenuate portions thereof that are associated with frequencies higher than a frequency range of interest to the transient object locating and tracking system 200. A second filter, such as for example, a Gaussian filter or a notch filter, may then be applied to the once-filtered pressure data samples to better isolate pressure data points that reside within a frequency range of interest (e.g., 6 Hz to 7 Hz). The filtered pressure data samples may subsequently be used to generate the training dataset 230 that can be used to train the machine learning model 204. The filtering operation(s) can make the machine learning model training process more efficient, and may result in a more accurate predictive model.

During a test conducted by the conduit monitoring system 100, the overall length of time during which a pressure wave propagates in the conduit and continues to result in measurable pressure wave reflections may far exceed a time period of interest, which may be a time period bounded by the largest points of created acoustic energy in the conduit during the test. This commonly occurs, for example, over a time period beginning at a first point where a downstream bleed valve is opened to produce pressure wave in the conduit monitored by the conduit monitoring system 100, and a subsequent second point where the valve is closed. As a machine learning model can be trained on pressure data collected over the course of many (e.g., hundreds or thousands of) monitoring operations, it can be advantageous to focus on the pressure profile in the conduit during only a time period of interest.

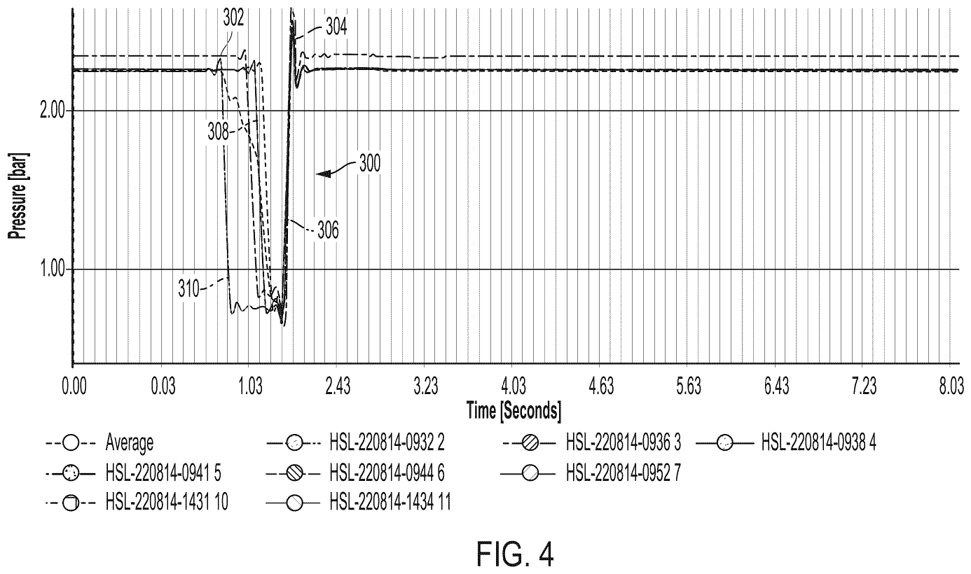

FIG. 4 graphically depicts a plurality of overlaid conduit pressure profiles 300, each of which is limited to only a time period of interest and is calculated based on pressure data samples collected by a conduit monitoring system during a unique conduit test operation on a given conduit. A training dataset may be comprised of a multitude of such filtered pressure data samples. The time period of interest corresponding to each pressure profile is, in this example, a time period beginning at a first pressure bleed off point 302 resulting from opening of a bleed valve that also produced a pressure wave in a conduit monitored by a conduit monitoring system, and a subsequent second point 304 where a pressure wave reflection from a transient object in the conduit was received by a sensor of the conduit monitoring system. A pressure recovery portion 306 of the pressure profile 300 occurs between the pressure bleed off point 302 and the point 304 at which a reflection of the pressure wave caused by a transient object is received by the sensor of the conduit monitoring system. The observed pressure values in the conduit during the time period of interest of each corresponding test operation performed by the conduit monitoring systems are represented by the collection of overlaid individual conduit pressure profiles 300. An average pressure profile 308 representing the average of the pressure values associated with the overlaid individual pressure profiles 300 is also shown in FIG. 4, as is the first derivative 310 of the average conduit pressure profile 308.

Conduit pressures and pressure profiles, transient object location, transient object speed of movement, transient object direction of movement, transient object distance to travel, etc., can be calculated by the predictive model 206 according to known techniques. For example, by knowing, measuring or otherwise determining other characteristics about a conduit of interest (e.g., conduit length and diameter) and the fluid in the conduit, mathematical equations can be used by the predictive model to calculate pressures and pressure profiles relative to a conduit of interest. Likewise, by knowing, measuring or otherwise determining the speed at which the pressure wave travels through the fluid in the conduit of interest, the location of a transient object, and the speed and direction of movement of the transient object in a conduit of interest, can be predicted by the predictive model. For example, with the speed at which the pressure wave travels through the fluid in the conduit of interest known, the location of a transient object within the conduit of interest can be predicted based on the time between introduction of a pressure wave by a conduit monitoring system into the fluid within a conduit of interest and arrival of a transient object-reflected pressure wave at a sensor of the conduit monitoring system. Likewise, by measuring the difference between the time required to receive successive reflected pressure waves (as may be determined from datasets iterated over time), the speed and direction of movement of the transient object can be determined. Other location and movement determination techniques can also be employed.

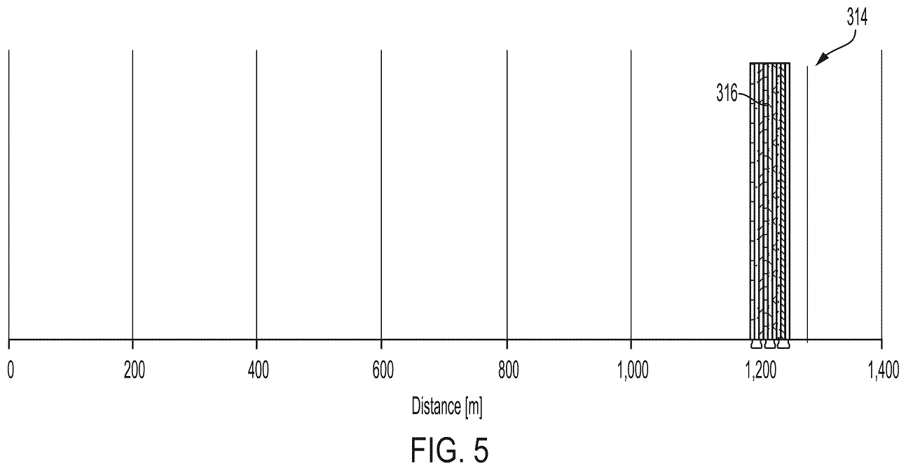

FIG. 5 is a hybrid bar chart that graphically represents a predicted range of transient object locations within the conduit associated with the pressure data samples of FIG. 4. More specifically, each bar of the hybrid bar chart represents a predicted transient object location determined from a corresponding one of the pressure profiles 300 shown in FIG. 4. As shown, the collection of bars 314 together define the predicted location range of the transient object, which is shown to be between approximately 1,200-1,250 meters from the location of the conduit monitoring system sensor in this example. An average location based on the grouping of predicted locations is also represented by a line 316.

FIG. 5 also indicates a deviation of approximately 50 meters between predicted locations of a transient object based on the pressure data samples 300 of FIG. 4. As described above, the machine learning model can be trained in a manner that seeks to minimize the standard deviation between calculated transient object locations.

Various information may be presented in a notification generated by a transient object locating and tracking system relative to a transient object in a conduit of interest. For example, when the notification is associated with locating and tracking a pig in a conduit of interest, the notification may include information such as the pig location, the pig velocity, and the distance to travel (i.e., the remainder of the planned distance the pig has left to travel). The information presented by the notification may be alphanumeric, graphical, both, etc.

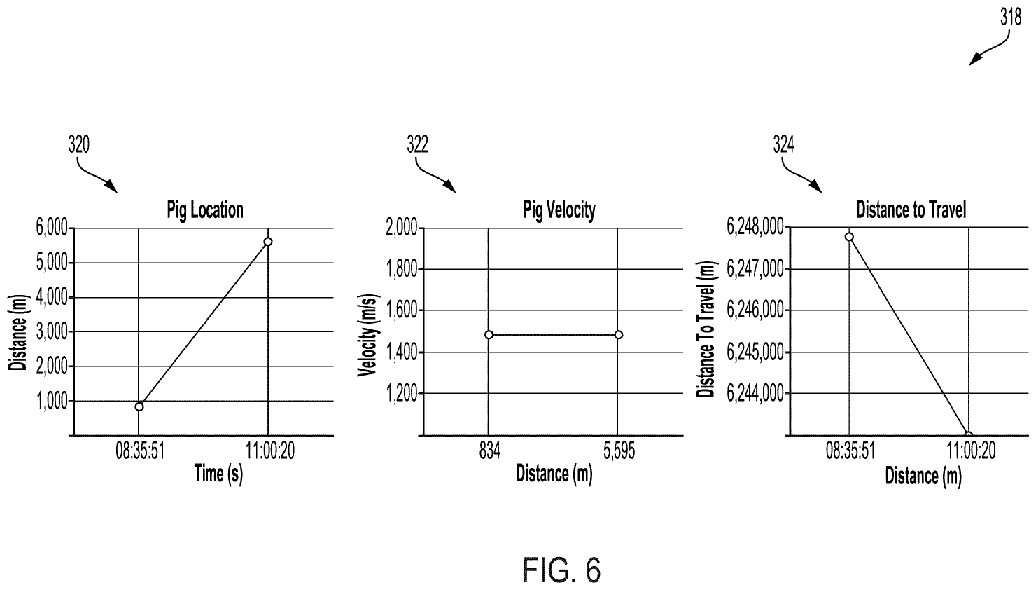

FIG. 6 illustrates various information that may be presented in one example of a notification 318 generated by a transient object locating and tracking system relative to a transient object in a conduit of interest. As shown in this particular example, the notification 318 is associated with locating and tracking a pig in a conduit of interest, and includes information such as the pig location 320, the pig velocity 322, and the distance to travel (i.e., the remainder of the planned distance the pig has left to travel) 324. The information presented by the notification 318 may be alphanumeric, graphical, or both. Information other than or in addition to the information shown in the notification 318 of FIG. 6, may be presented in other notification examples.

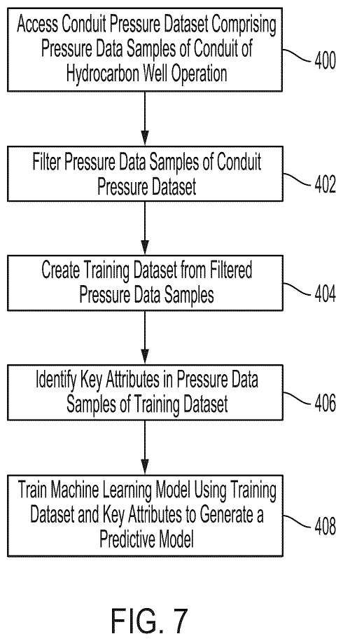

FIG. 7 is a flow chart of a method of training a machine learning model to locate and track a transient object in a hydrocarbon well conduit. According to the method example of FIG. 7, a conduit pressure dataset comprising a multitude of pressure data samples for a conduit of a hydrocarbon well operation is accessed at block 400 by a processor, such as but not limited to a processor of an above-described transient object locating and tracking system. At block 402, the processor filters the pressure data samples of the conduit pressure dataset. Filtering may be performed to eliminate noise and to focus the training dataset. The filtering may be accomplished, for example, by applying a low-pass filter to the pressure data samples of the conduit pressure dataset and by applying a second filter to the pressure data samples subsequent to applying the low-pass filter to the pressure data samples. At block 404, the processor generates, by the filtering of the pressure data samples of the conduit pressure dataset, a training dataset having a multitude of filtered pressure data samples. At block 406, the processor can identify key attributes in the filtered pressure data samples of the training dataset. In at least some examples, the key attributes can be identified based on calculated first derivatives of the filtered pressure data samples of the conduit pressure dataset. The processor may then, at block 408, train a machine learning model using the training dataset and the key attributes to generate a predictive model. The machine learning model can be trained to minimize standard deviation and mean average between distance to transient object predictions calculated from at least some of the filtered pressure data samples in the training dataset. In at least some examples, the predictive model can be subsequently used to predict a location of a transient object in a conduit of interest, as well as the speed and direction of movement of the transient object, by applying the predictive model to pressure measurements associated with the conduit of interest. In at least some examples, the processor can also generate a notification of the prediction. The notification may include, for example, the location, speed, and direction of movement of the transient object in the conduit of interest, or may cause other actions to be taken.

For purposes of illustration, various examples have been provided above relative to hydrocarbon well conduits, fluids, and operations. However, it should be understood that examples can also be used to track transient objects in other types of conduits. For example, a system can be used to track transient objects in conduits carrying water, hydrogen, carbon dioxide, or other fluids. In one particular example, a system and method can be used to track transient objects in a conduit of a carbon capture, utilization and storage (CCUS) operation, where carbon dioxide is captured from a source and transported to another location for use or for geologic sequestration in an underground formation.

According to aspects of the present disclosure, a system, a method, and a non-transitory computer-readable medium, are provided according to one or more of the following examples. As used below, any reference to a series of examples is to be understood as a reference to each of those examples disjunctively (e.g., “Examples 1-4” is to be understood as “Examples 1, 2, 3, or 4”).

Example 1 is a system, comprising: a processor; and a memory including instructions that are executable by the processor for causing the processor to: access a conduit pressure dataset comprising a multitude of measured pressure data samples of a conduit of a hydrocarbon well operation; filter the pressure data samples of the conduit pressure dataset by applying a low-pass filter to the pressure data samples and by applying a second filter to the pressure data samples subsequent to applying the low-pass filter to the pressure data samples, to generate a training dataset having a multitude of filtered pressure data samples; identify a plurality of key attributes in each of the filtered pressure data samples of the training dataset, at least one key attribute of the plurality of key attributes being a point of largest measured acoustic energy in the conduit; train a machine learning model using the training dataset and the plurality of key attributes to minimize standard deviation and mean average between distance to transient object predictions calculated from at least some of the filtered pressure data samples in the training dataset, to generate a predictive model.

Example 2 is the system of example 1, wherein: the pressure data samples are produced by a conduit monitoring system configured to introduce a pressure wave into the conduit and to measure a magnitude of reflected pressure waves using at least one sensor; the conduit monitoring system is communicatively coupled to a computing device of the system, the computing device including the processor, the memory, and the instructions; and the instructions are further executable by the processor for causing the computing device to receive the pressure data samples from the conduit monitoring system.

Example 3 is the system of example 1, wherein the conduit pressure dataset includes a first set of pressure data associated with a conduit known to include a transient object that is a pig, a second set of pressure data associated with a conduit known to include a blockage other than a pig, and a third set of pressure data associated with an ideal conduit.

Example 4 is the system of example 1, wherein the conduit pressure dataset comprises pressure data samples recorded only during a time period of interest.

Example 5 is the system of example 1, wherein the low-pass filter and the second filter are usable in combination to remove noise from the pressure data samples and to focus the training dataset on a frequency range of interest of between 6 Hz to 7 Hz; and the low-pass filter is a Butterworth filter and the second filter is a Gaussian filter or a notch filter.

Example 6 is the system of example 1, wherein the instructions are further executable by the processor for causing the processor to: after filtering of the pressure data samples of the conduit pressure dataset, calculate at least a first derivative of each of the pressure data samples of the conduit pressure dataset; and identify the plurality of key attributes in each of the pressure data samples of the conduit pressure dataset from the first derivative of each of the pressure data samples of the conduit pressure dataset.

Example 7 is the system of example 1, wherein the instructions are further executable by the processor for causing the processor to: predict a location and movement of a transient object in a conduit of interest by applying the predictive model to datasets comprising measured pressure data associated with the conduit of interest and iterated over time, and analyzing pressure profiles defined by the measured pressure data; and output a command to execute an action selected from the group consisting of generating a notification indicating at least a location of the transient object, scheduling a removal of the transient object when the transient object is a pig, initiating a remediation action relative to the transient object when the transient object is a blockage, and combinations thereof.

Example 8 is a computer-implemented method comprising: accessing, by a processor, a conduit pressure dataset comprising a multitude of measured pressure data samples for a conduit of a hydrocarbon well operation; filtering, by the processor, the pressure data samples of the conduit pressure dataset by applying a low-pass filter to the pressure data samples and by applying a second filter to the pressure data samples subsequent to applying the low-pass filter to the pressure data samples, to generate a training dataset having a multitude of filtered pressure data samples; identifying a plurality of key attributes in each of the filtered pressure data samples of the training dataset, at least one key attribute of the plurality of key attributes being a point of largest measured acoustic energy in the conduit; training, by the processor, a machine learning model using the training dataset and the plurality of key attributes to minimize standard deviation and mean average between distance to transient object predictions calculated from at least some of the filtered pressure data samples in the training dataset, to generate a predictive model.

Example 9 is the computer-implemented method of example 8, wherein the conduit pressure dataset includes a first set of pressure data associated with a conduit known to include a transient object that is a pig, a second set of pressure data associated with a conduit known to include a blockage other than a pig, and a third set of pressure data associated with an ideal conduit.

Example 10 is the computer-implemented method of example 8, wherein the pressure data samples in the conduit pressure dataset comprise pressure data recorded only during a time period of interest.

Example 11 is the computer-implemented method of example 8, wherein: the low-pass filter and the second filter are usable in combination to remove noise from the pressure data samples and to focus the training dataset on a frequency range of interest of between 6 Hz to 7 Hz; and the low-pass filter is a Butterworth filter and the second filter is a Gaussian filter or a notch filter.

Example 12 is the computer-implemented method of example 8, further comprising: after filtering of the pressure data samples of the conduit pressure dataset, calculating, by the processor, a first derivative of each of the pressure data samples of the conduit pressure dataset; and identifying, by the processor, the plurality of key attributes in each of the pressure data samples of the conduit pressure dataset from the first derivative of each of the pressure data samples of the conduit pressure dataset.

Example 13 is the computer-implemented method of example 8, further comprising: predicting, by the processor, a location and movement of a transient object in a conduit of interest by applying the predictive model to datasets comprising measured pressure data associated with the conduit of interest and iterated over time, and analyzing pressure profiles defined by the measured pressure data; and in response to predicting a location and movement of a transient object in the conduit of interest, outputting by the processor, a command to execute an action selected from the group consisting of generating a notification indicating at least a location of the transient object, scheduling a removal of the transient object when the transient object is a pig, initiating a remediation action relative to the transient object when the transient object is a blockage, and combinations thereof.

Example 14 is the computer-implemented method of example 13, wherein predicting the location and movement of the transient object in the conduit of interest includes providing information selected from the group consisting of transient object speed, transient object direction of movement, transient object distance to travel, and combinations thereof.

Example 15 is a non-transitory computer-readable medium comprising instructions that are executable by a processor for causing the processor to: access a conduit pressure dataset comprising a multitude of measured pressure data samples of a conduit of a hydrocarbon well operation; filter the pressure data samples of the conduit pressure dataset by applying a low-pass filter to the pressure data samples and by applying a second filter to the pressure data samples subsequent to applying the low-pass filter to the pressure data samples, to generate a training dataset having a multitude of filtered pressure data samples; identify a plurality of key attributes in each of the filtered pressure data samples of the training dataset, at least one key attribute of the plurality of key attributes being a point of largest measured acoustic energy in the conduit; train a machine learning model using the training dataset and the plurality of key attributes to minimize standard deviation and mean average between distance to transient object predictions calculated from at least some of the filtered pressure data samples in the training dataset, to generate a predictive model.

Example 16 is the non-transitory computer-readable medium of example 15, wherein: the pressure data samples are produced by a conduit monitoring system configured to introduce a pressure wave into the conduit and to measure a magnitude of reflected pressure waves using at least one sensor; the conduit monitoring system is communicatively coupled to a computing device of the system, the computing device including the processor, the memory, and the instructions; and the instructions are further executable by the processor for causing the computing device to receive the pressure data samples from the conduit monitoring system.

Example 17 is the non-transitory computer-readable medium of example 15, wherein: the conduit pressure dataset includes a first set of pressure data associated with a conduit known to include a transient object that is a pig, a second set of pressure data associated with a conduit known to include a blockage other than a pig, and a third set of pressure data associated with an ideal conduit; and the pressure data in the conduit pressure dataset is pressure data recorded only during a time period of interest.

Example 18 is the non-transitory computer-readable medium of example 15, wherein the low-pass filter and the second filter are usable in combination to remove noise from the pressure data samples and to focus the training dataset on a frequency range of interest of between 6 Hz to 7 Hz; and the low-pass filter is a Butterworth filter and the second filter is a Gaussian filter or a notch filter.

Example 19 is the non-transitory computer-readable medium of example 15, wherein the instructions are further executable by the processor for causing the processor to: after filtering of the pressure data samples of the conduit pressure dataset, calculate at least a first derivative of each of the pressure data samples of the conduit pressure dataset; and identify the plurality of key attributes in each of the pressure data samples of the conduit pressure dataset from the first derivative of each of the pressure data samples of the conduit pressure dataset.

Example 20 is the non-transitory computer-readable medium of example 15, wherein the instructions are further executable by the processor for causing the processor to: predict a location and movement of a transient object in a conduit of interest by applying the predictive model to datasets comprising measured pressure data associated with the conduit of interest and iterated over time, and analyzing pressure profiles defined by the measured pressure data; and output a command to execute an action selected from the group consisting of generating a notification indicating at least a location of the transient object, scheduling a removal of the transient object when the transient object is a pig, initiating a remediation action relative to the transient object when the transient object is a blockage, and combinations thereof.

The foregoing description of certain examples, including illustrated examples, has been presented only for the purpose of illustration and description and is not intended to be exhaustive or to limit the disclosure to the precise forms disclosed. Numerous modifications, adaptations, and uses thereof will be apparent to those skilled in the art without departing from the scope of the disclosure.

What is claimed is:

1. A system, comprising:
a processor; and
a memory including instructions that are executable by the processor for causing the processor to:
access a conduit pressure dataset comprising a multitude of measured pressure data samples of a conduit of a hydrocarbon well operation;
filter the pressure data samples of the conduit pressure dataset by applying a low-pass filter to the pressure data samples and by applying a second filter to the pressure data samples subsequent to applying the low-pass filter to the pressure data samples, to generate a training dataset having a multitude of filtered pressure data samples;
identify a plurality of key attributes in each of the filtered pressure data samples of the training dataset, at least one key attribute of the plurality of key attributes being a point of largest measured acoustic energy in the conduit;
train a machine learning model using the training dataset and the plurality of key attributes to minimize standard deviation and mean average between distance to transient object predictions calculated from at least some of the filtered pressure data samples in the training dataset, to generate a predictive model.

2. The system of claim 1, wherein:
the pressure data samples are produced by a conduit monitoring system configured to introduce a pressure wave into the conduit and to measure a magnitude of reflected pressure waves using at least one sensor;
the conduit monitoring system is communicatively coupled to a computing device of the system, the computing device including the processor, the memory, and the instructions; and
the instructions are further executable by the processor for causing the computing device to receive the pressure data samples from the conduit monitoring system.

3. The system of claim 1, wherein the conduit pressure dataset includes a first set of pressure data associated with a conduit known to include a transient object that is a pig, a second set of pressure data associated with a conduit known to include a blockage other than a pig, and a third set of pressure data associated with an ideal conduit.

4. The system of claim 1, wherein the conduit pressure dataset comprises pressure data samples recorded only during a time period of interest.

5. The system of claim 1, wherein
the low-pass filter and the second filter are usable in combination to remove noise from the pressure data samples and to focus the training dataset on a frequency range of interest of between 6 Hz to 7 Hz; and
the low-pass filter is a Butterworth filter and the second filter is a Gaussian filter or a notch filter.

6. The system of claim 1, wherein the instructions are further executable by the processor for causing the processor to:
after filtering of the pressure data samples of the conduit pressure dataset, calculate at least a first derivative of each of the pressure data samples of the conduit pressure dataset; and
identify the plurality of key attributes in each of the pressure data samples of the conduit pressure dataset from the first derivative of each of the pressure data samples of the conduit pressure dataset.

7. The system of claim 1, wherein the instructions are further executable by the processor for causing the processor to:
predict a location and movement of a transient object in a conduit of interest by applying the predictive model to datasets comprising measured pressure data associated with the conduit of interest and iterated over time, and analyzing pressure profiles defined by the measured pressure data; and
output a command to execute an action selected from the group consisting of generating a notification indicating at least a location of the transient object, scheduling a removal of the transient object when the transient object is a pig, initiating a remediation action relative to the transient object when the transient object is a blockage, and combinations thereof.

8. A computer-implemented method comprising:
accessing, by a processor, a conduit pressure dataset comprising a multitude of measured pressure data samples for a conduit of a hydrocarbon well operation;
filtering, by the processor, the pressure data samples of the conduit pressure dataset by applying a low-pass filter to the pressure data samples and by applying a second filter to the pressure data samples subsequent to applying the low-pass filter to the pressure data samples, to generate a training dataset having a multitude of filtered pressure data samples;
identifying a plurality of key attributes in each of the filtered pressure data samples of the training dataset, at least one key attribute of the plurality of key attributes being a point of largest measured acoustic energy in the conduit;
training, by the processor, a machine learning model using the training dataset and the plurality of key attributes to minimize standard deviation and mean average between distance to transient object predictions calculated from at least some of the filtered pressure data samples in the training dataset, to generate a predictive model.

9. The computer-implemented method of claim 8, wherein the conduit pressure dataset includes a first set of pressure data associated with a conduit known to include a transient object that is a pig, a second set of pressure data associated with a conduit known to include a blockage other than a pig, and a third set of pressure data associated with an ideal conduit.

10. The computer-implemented method of claim 8, wherein the pressure data samples in the conduit pressure dataset comprise pressure data recorded only during a time period of interest.

11. The computer-implemented method of claim 8, wherein:
the low-pass filter and the second filter are usable in combination to remove noise from the pressure data samples and to focus the training dataset on a frequency range of interest of between 6 Hz to 7 Hz; and
the low-pass filter is a Butterworth filter and the second filter is a Gaussian filter or a notch filter.

12. The computer-implemented method of claim 8, further comprising:
after filtering of the pressure data samples of the conduit pressure dataset, calculating, by the processor, a first derivative of each of the pressure data samples of the conduit pressure dataset; and
identifying, by the processor, the plurality of key attributes in each of the pressure data samples of the conduit pressure dataset from the first derivative of each of the pressure data samples of the conduit pressure dataset.

13. The computer-implemented method of claim 8, further comprising:
predicting, by the processor, a location and movement of a transient object in a conduit of interest by applying the predictive model to datasets comprising measured pressure data associated with the conduit of interest and iterated over time, and analyzing pressure profiles defined by the measured pressure data; and
in response to predicting a location and movement of a transient object in the conduit of interest, outputting by the processor, a command to execute an action selected from the group consisting of generating a notification indicating at least a location of the transient object, scheduling a removal of the transient object when the transient object is a pig, initiating a remediation action relative to the transient object when the transient object is a blockage, and combinations thereof.

14. The computer-implemented method of claim 13, wherein predicting the location and movement of the transient object in the conduit of interest includes providing information selected from the group consisting of transient object speed, transient object direction of movement, transient object distance to travel, and combinations thereof.

15. A non-transitory computer-readable medium comprising instructions that are executable by a processor for causing the processor to:
access a conduit pressure dataset comprising a multitude of measured pressure data samples of a conduit of a hydrocarbon well operation;
filter the pressure data samples of the conduit pressure dataset by applying a low-pass filter to the pressure data samples and by applying a second filter to the pressure data samples subsequent to applying the low-pass filter to the pressure data samples, to generate a training dataset having a multitude of filtered pressure data samples;
identify a plurality of key attributes in each of the filtered pressure data samples of the training dataset, at least one key attribute of the plurality of key attributes being a point of largest measured acoustic energy in the conduit;
train a machine learning model using the training dataset and the plurality of key attributes to minimize standard deviation and mean average between distance to transient object predictions calculated from at least some of the filtered pressure data samples in the training dataset, to generate a predictive model.

16. The non-transitory computer-readable medium of claim 15, wherein:
the pressure data samples are produced by a conduit monitoring system configured to introduce a pressure wave into the conduit and to measure a magnitude of reflected pressure waves using at least one sensor;
the conduit monitoring system is communicatively coupled to a computing device of the system, the computing device including the processor, the memory, and the instructions; and
the instructions are further executable by the processor for causing the computing device to receive the pressure data samples from the conduit monitoring system.

17. The non-transitory computer-readable medium of claim 15, wherein:
the conduit pressure dataset includes a first set of pressure data associated with a conduit known to include a transient object that is a pig, a second set of pressure data associated with a conduit known to include a blockage other than a pig, and a third set of pressure data associated with an ideal conduit; and
the pressure data in the conduit pressure dataset is pressure data recorded only during a time period of interest.

18. The non-transitory computer-readable medium of claim 15, wherein the low-pass filter and the second filter are usable in combination to remove noise from the pressure data samples and to focus the training dataset on a frequency range of interest of between 6 Hz to 7 Hz; and
the low-pass filter is a Butterworth filter and the second filter is a Gaussian filter or a notch filter.

19. The non-transitory computer-readable medium of claim 15, wherein the instructions are further executable by the processor for causing the processor to:
after filtering of the pressure data samples of the conduit pressure dataset, calculate at least a first derivative of each of the pressure data samples of the conduit pressure dataset; and
identify the plurality of key attributes in each of the pressure data samples of the conduit pressure dataset from the first derivative of each of the pressure data samples of the conduit pressure dataset.

20. The non-transitory computer-readable medium of claim 15, wherein the instructions are further executable by the processor for causing the processor to:
predict a location and movement of a transient object in a conduit of interest by applying the predictive model to datasets comprising measured pressure data associated with the conduit of interest and iterated over time, and analyzing pressure profiles defined by the measured pressure data; and
output a command to execute an action selected from the group consisting of generating a notification indicating at least a location of the transient object, scheduling a removal of the transient object when the transient object is a pig, initiating a remediation action relative to the transient object when the transient object is a blockage, and combinations thereof.
